(19) United States
(12) Patent Application Publication
(10) Pub. No.: US 2023/0100911 A1
(43) Pub. Date: Mar. 30, 2023

(54) PARTIAL DICING PROCESS FOR WAFER-LEVEL PACKAGING

(71) Applicant: Texas Instruments Incorporated, Dallas, TX (US)

(72) Inventors: Peter SMEYS, San Jose, CA (US); Ting-Ta YEN, San Jose, CA (US)

(21) Appl. No.: 17/488,586

(22) Filed: Sep. 29, 2021

(51) Int. Cl. H01L 21/78; B81B 7/00; B81C 3/00; H01L 23/00; H01L 23/544

(52) U.S. Cl. CPC H01L 21/78; B81B 7/0058; B81C 3/001; H01L 24/94; H01L 23/544; B81C 2203/0109; B81C 2203/0118; H01L 2223/54426

(57) ABSTRACT

An encapsulation chip manufacturing method includes forming first and second dicing grooves in a surface of a cap wafer and aligning the cap wafer and a device substrate such that the surface of the cap wafer faces a surface of the device substrate. The device substrate includes a device affixed to the surface and a bond pad on the surface and coupled to the device. The cap wafer is bonded to the device substrate and partially diced at the first and second dicing grooves such that the bond pad is exposed. Aligning the cap wafer and the device substrate includes aligning the first and second dicing grooves between the bond pad and a bonding area at which the cap wafer is bonded to the device substrate. A width of the first and second dicing grooves prevents cap wafer dust formed during the partial dicing from falling on the bond pad.

### BACKGROUND

Wafer-level packaging is a packaging technique often used to isolate sensitive circuits and components from the package environment. For example, microelectromechanical systems (MEMS) such as bulk acoustic wave resonators, accelerometers, optical sensors, microactuators, and the like can be sensitive to vertical or lateral stresses from their packages. In wafer-level packaging, the MEMS is affixed to a substrate by an anchor, tether, or a spring, and couples an electric signal to a bond pad on the substrate. A cap wafer is affixed to the substrate over the MEMS and bond pad, and partially diced to expose the bond pad.

However, the partial dicing process can require high-precision alignment to ensure the cap wafer is diced at an appropriate location and high-precision depth control to ensure the dicing blades do not cut too deep and damage the substrate underneath. A misaligned blade can dice the cap wafer too dose to a bonding site and compromise the bonding between the cap wafer and the substrate. In addition, a misaligned blade can dice the cap wafer in a manner that does not fully expose the bond pad or deposits dust onto the bond pad, damaging it. A too-low height setting for the blade can cause the blade to dice the cap wafer too deeply and can damage the substrate and bond pad beneath, while a too-high setting for the blade can cause the blade to not fully cut through the cap wafer.

### SUMMARY

An encapsulation chip manufacturing method comprises forming a first dicing groove and a second dicing groove in a surface of a cap wafer and aligning the cap wafer and a device substrate such that the surface of the cap wafer faces a surface of the device substrate. The device substrate includes a device affixed to the surface of the device substrate and a bond pad on the surface of the device substrate and coupled to the device. The cap wafer is then bonded to the device substrate and partially diced at the first and second dicing grooves, such that the bond pad is exposed. In some implementations, aligning the cap wafer and the device substrate comprises aligning the first and second dicing grooves between the bond pad and a bonding area at which the cap wafer is bonded to the device substrate. A width of the first and second dicing grooves is such that cap wafer dust formed during the partial dicing does not fall on the bond pad.

In some embodiments, bonding the cap wafer to the device includes bonding a first portion of the cap wafer and a first portion of the device substrate with a bonding polymer and bonding a second portion of the cap wafer and a second portion of the device substrate with the bonding polymer. The first and second portions of the device substrate are on opposite sides of the device. In some implementations, the second portion of the device substrate is between the device and the bond pad. Aligning the cap wafer and the device substrate includes aligning at least one of the first and second dicing grooves between the second portion of the device substrate and the bond pad in some embodiments.

Partially dicing the cap wafer and the first and second dicing grooves comprises sawing through the cap wafer to a depth of the first and second dicing grooves, in some implementations. The device comprises one of an integrated circuit and a microelectromechanical system device.

### BRIEF DESCRIPTION OF THE DRAWINGS

FIG. 1 illustrates a cross-section of a semiconductor device during the partial dicing step of the wafer-level packaging.

FIG. 2A illustrates a cross-section of a semiconductor device during a capsulation wafer bonding step of the wafer-level packaging.

FIG. 2B illustrates a cross section of the semiconductor device shown in FIG. 2A during a partial dicing step of the wafer-level packaging.

The same reference number is used in the drawings for the same or similar (either by function and/or structure) features.

### DETAILED DESCRIPTION

The described partial dicing processes include forming dicing grooves on an inner surface of a cap wafer. A device substrate has an integrated circuit or a MEMS device and a bond pad affixed to a substrate surface. The device substrate and the cap wafer are bonded together at bonding areas and aligned such that the inner surface of the cap wafer faces the substrate surface and the dicing grooves are aligned between the bonding area and the bond pad. The cap wafer and the device substrate are bonded together, and the cap wafer is partially diced at the dicing grooves to expose the bond pad on the substrate surface. During the partial dicing process, the blades are aligned with portions of an outer surface of the cap wafer that correspond to the dicing groove and saw partway through the cap wafer to a depth of the dicing grooves.

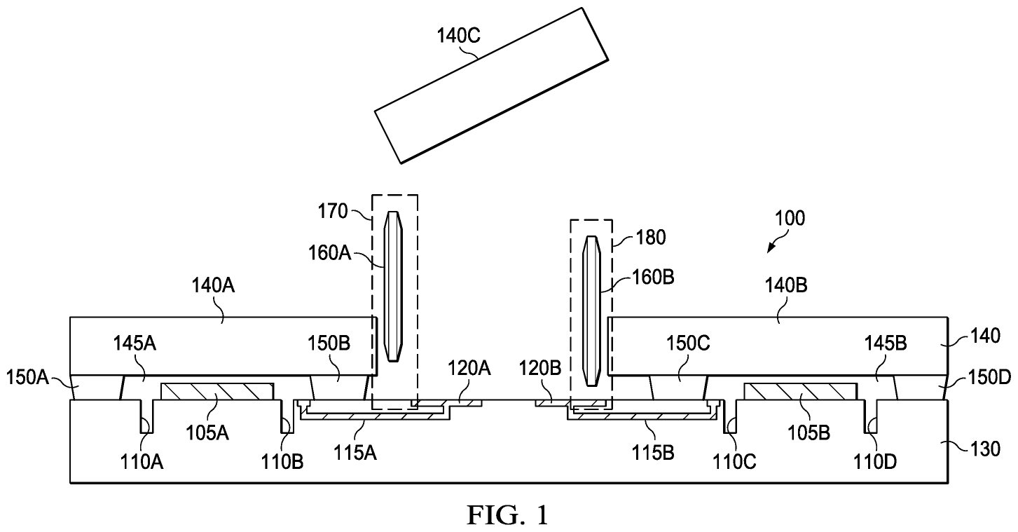

FIG. 1 illustrates a cross-section of a semiconductor device 100 during the partial dicing step of the wafer-level packaging. The semiconductor device 100 includes stress-sensitive devices 105A and 1058; isolation trenches 110A, 1108, 110C, and 110D; leads or routing traces 115A and 115B with bond pads 120A and 120B, respectively; substrate 130; a cap wafer 140; and bonding polymer 150A, 150B, 150C, and 150D. The stress-sensitive devices 105A and 105B can be any kind of microelectromechanical system (MEMS), such as a bulk acoustic wave resonator or the like that is sensitive to stress. The substrate 130 can be any appropriate device substrate, such as a silicon wafer. Similarly, the cap wafer 140 can be any appropriate wafer, such as a silicon wafer, a gallium-nitride wafer, a gallium-arsenic wafer, and the like. The cap wafer 140 can be the same or different material as the substrate 130.

The stress-sensitive device 105A is affixed to a surface of the substrate 130 between the isolation trenches 110A and 1108, and the stress-sensitive device 1058 is affixed to the surface of the substrate 130 between the isolation trenches 110C and 110D. In this example, the stress-sensitive devices 105A and 1058 are formed separately from the substrate 130 and affixed to the surface of the substrate 130. In other implementations, the stress-sensitive devices 105A and 1058 can be formed directly on the surface of substrate 130.

The lead 115A couples the stress-sensitive device 105A to the bond pad 120A, and the lead 115B couples the stress-sensitive device 105B to the bond pad 120B. The cap wafer 140 is bonded to the surface of the substrate 130 using the bonding polymers 150A, 150B, 150C, and 150D to form cavities 145A and 145B over and around the stress-sensitive devices 105A and 105B, respectively. The bonding polymers 150A, 150B, 150C, and 150D are arranged on the surface of the substrate 130 outside the isolation trenches 110A, 110B, 110C, and 110D from the stress-sensitive devices 105A and 105B. The bonding polymer 150B is further arranged between the isolation trench 110B and the bond pad 120A, and the bonding polymer 150C is further arranged between the isolation trench 110C and the bond pad 120B.

During the partial dicing step of the wafer-level packaging process, the blades 160A and 160B cut the cap wafer 140 into three portions 140A, 140B, and 140C. The cap wafer portion 140A remains affixed to the substrate 130 over the stress-sensitive device 105A by the bonding polymers 150A and 150B, and the cap wafer portion 140B remains affixed to the substrate 130 over the stress-sensitive device 105B by the bonding polymers 150C and 150D. The cap wafer portion 140C is removed from between portions 140A and 140B to expose the bond pads 120A and 120B. The partial dicing process requires high-precision alignment of the blades 160A and 160B over the cap wafer 140 to ensure the cap wafer 140 is diced at an appropriate location.

In callout 170, the blade 160A is aligned too close to the bonding polymer 150B and may affect how well the cap wafer 140A is affixed to the substrate 130. For example, the blade 160A can cut away a portion of the bonding polymer 150B, leaving an insufficient amount of bonding polymer 150B to hold the cap wafer 140A to the substrate 130. As another example, the blade 160A can cut the cap wafer 140 at a portion that is bonded by the bonding polymer 150B, such that the cap wafer portion 140C is at least partially adhered to the substrate 130 by the bonding polymer 150B. Removing the cap wafer portion 140C to expose the bond pads 120A and 120B then requires additional and difficult processing. For example, an etching process to remove a portion of the bonding polymer 150B adhering the cap wafer portion 140C to substrate 130 must not affect the integrity of the remaining bonding polymer 150B or damage the bond pads 120A and 120B.

In addition, the height of blades 160A and 160B must be carefully controlled to ensure that the blades 160A and 160B cut all the way through cap wafer 140 to expose the bond pads 120A and 120B but do not cut too deep so that the substrate 130 is damaged. In callout 180, the blade 160B cuts too deeply through the cap wafer 140 and damages the bond pad 120B and substrate 130 beneath. Even with high-precision alignment and height control, the partial dicing process can cause dust from cap wafer 140 to land on bond pads 120A and 120B, causing damage.

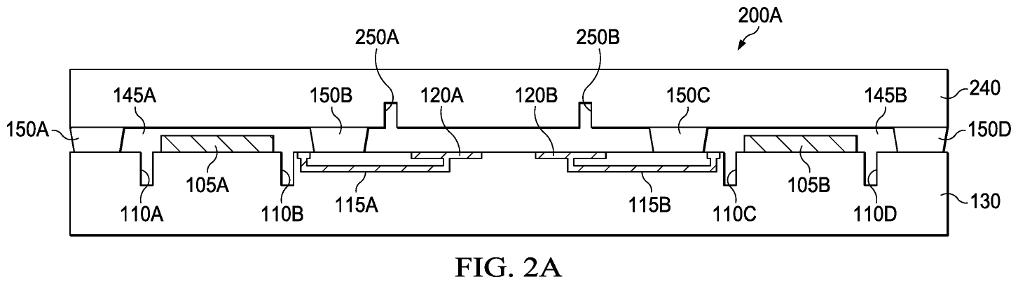

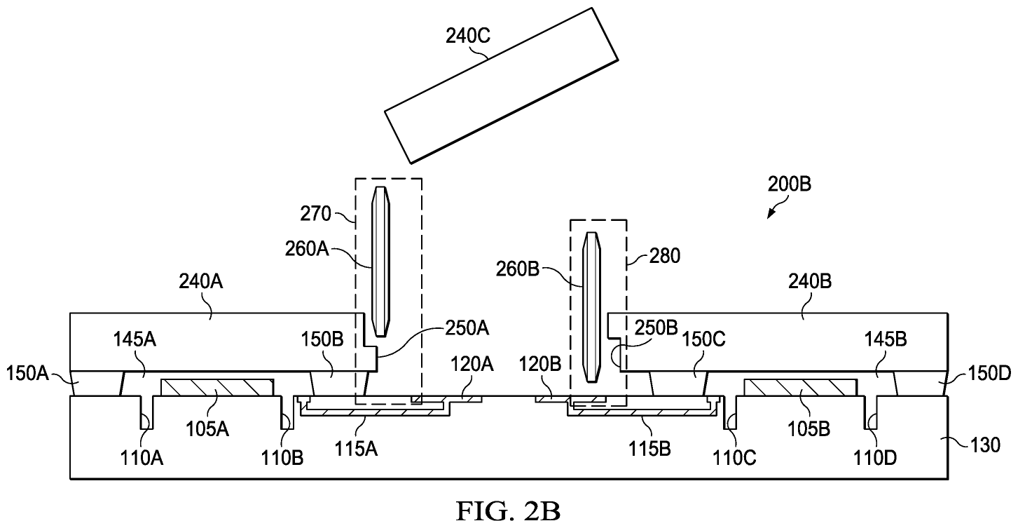

FIG. 2A illustrates a cross-section 200A of a semiconductor device 200 during a capsulation wafer bonding step of the wafer-level packaging. The semiconductor device 200 and cap wafer 240 are similar to the semiconductor device 100 and cap wafer 140, respectively, shown in FIG. 1, but cap wafer 240 includes dicing grooves 250A and 250B cut into an inner surface of the cap wafer 240 facing the stress-sensitive devices 105A and 105B. The cap wafer 240 can be any appropriate wafer, such as a silicon wafer, a gallium-nitride wafer, a gallium-arsenic wafer, and the like. The cap wafer 240 can be the same or different material as the substrate 130, and includes the dicing grooves 250A and 250B.

A depth and width of the dicing grooves 250A and 250B can be chosen based on the capabilities of the manufacturing system, as discussed further herein with respect to FIG. 2B. The dicing grooves 250A and 250B can be cut into the cap wafer 240 at any point in the manufacturing process before the cap wafer 240 is affixed to the substrate 130 by the bonding polymers 150A, 150B, 150C, and 150D. For example, the dicing grooves 250A and 250B can be cut into the cap wafer 240 before a layer of the bonding polymer is spun onto the inner surface of the cap wafer and etched away into the bonding polymers 150A, 150B, 150C, and 150D.

During the capsulation wafer bonding step, the cap wafer 240 is aligned over the substrate 130 such that the dicing groove 250A and the bonding polymer 150B are positioned between the isolation trench 110B and the bond pad 120A. Similarly, the dicing groove 250B and the bonding polymer 150C are positioned between the isolation trench 110C and the bond pad 120B. In some manufacturing systems, it is simpler to align the cap wafer 240 over the substrate 130 than to align the blades 160A and 160B over the cap wafer 140 shown in FIG. 1.

FIG. 2B illustrates a cross section 200B of the semiconductor device 200 shown in FIG. 2A during a partial dicing step of the wafer-level encapsulation. The blades 260A and 260B cut the cap wafer 240 into three portions 240A, 240B, and 240C. The cap wafer portion 240A remains affixed to the substrate 130 over the stress-sensitive device 105A by the bonding polymers 150A and 150B, and the cap wafer portion 240B remains affixed to the substrate 130 over the stress-sensitive device 105B by the bonding polymers 150C and 150D. The cap wafer portion 240C is removed from between portions 240A and 240B to expose the bond pads 120A and 120B. The blades 260A and 260B are approximately aligned with the dicing grooves 250A and 250B and cut only partway through the cap wafer 240 to the dicing grooves 250A and 250B, rather than entirely through the cap wafer 140 as described herein with reference to FIG. 1.

The width and depth of dicing grooves 250A and 250B can be chosen to relax the manufacturing control for the blades 260A and 260B compared to the blades 160A and 160B described herein with reference to FIG. 1. For example, dicing grooves 250A and 250B can be wide enough to ease alignment control for the blades 260A and 260B but narrow enough to prevent dust from cap wafer 240 from falling on bond pads 120A and 120B. As another example, dicing grooves 250A and 250B can be deep enough to ease height control for the blades 260A and 260B and reduce the amount of dust from cap wafer 240 created during partial dicing but shallow enough to maintain the structural integrity of cap wafer 240 during the process of bonding cap wafer 240 to substrate 130.

In callout 270, the blade 260A is aligned too close to the bonding polymer 150B, similar to blade 160A in callout 170 shown in FIG. 1. However, because blade 260A is aligned with the dicing groove 250A and only cuts partway through the cap wafer 240, the blade 260A does not affect the bonding polymer 150B or how well the cap wafer 240B is affixed to the substrate 130. In callout 280, the blade 260B cuts too deeply through cap wafer 240, similar to the blade 160B in callout 180 shown in FIG. 1. However, because the blade 260B only cuts partway through the cap wafer 240 to dicing groove 250B, the too-deep cut of blade 260B does not damage the bond pad 120B or the substrate 130. Blades 260A and 260B create less dust from cap wafer 240 than blades 160A and 160B because blades 260A and 260B only cut partway through the cap wafer 240, and the dicing grooves 250A and 250B direct any dust created by the blades 260A and 260B away from the bond pads 120A and 120B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Unless otherwise stated, “aligned” or “substantially aligned” means the two are ninety percent or more aligned with each other. Unless otherwise stated, “about,” “approximately,” or “substantially” preceding a value means+/−10 percent of the stated value. Modifications are possible in the described examples, and other examples are possible within the scope of the claims.

Modifications are possible in the described embodiments, and other embodiments are possible, within the scope of the claims.

What is claimed is:

1. An encapsulation chip manufacturing method, comprising:
forming a first dicing groove and a second dicing groove in a surface of a cap wafer;
aligning the cap wafer and a device substrate such that the surface of the cap wafer faces a surface of the device substrate, wherein the device substrate comprises:
a device affixed to the surface of the device substrate, and
a bond pad on the surface of the device substrate and coupled to the device;
bonding the cap wafer to the device substrate; and
partially dicing the cap wafer at the first and second dicing grooves such that the bond pad is exposed.

2. The method of claim 1, wherein aligning the cap wafer and the device substrate comprises aligning the first and second dicing grooves between the bond pad and a bonding area, wherein the bonding area comprises an area at which the cap wafer is bonded to the device substrate.

3. The method of claim 2, wherein a width of the first and second dicing grooves is such that cap wafer dust formed during the partial dicing does not fall on the bond pad.

4. The method of claim 1, wherein bonding the cap wafer to the device substrate comprises:
bonding a first portion of the cap wafer and a first portion of the device substrate with a bonding polymer; and
bonding a second portion of the cap wafer and a second portion of the device substrate with the bonding polymer, wherein the first and second portions of the device substrate are on opposite sides of the device.

5. The method of claim 4, wherein the second portion of the device substrate is between the device and the bond pad.

6. The method of claim 5, wherein aligning the cap wafer and the device substrate comprises aligning at least one of the first dicing groove and the second dicing groove between the second portion of the device substrate and the bond pad.

7. The method of claim 1, wherein partially dicing the cap wafer at the first and second dicing grooves comprises sawing through the cap wafer to a depth of the first and second dicing grooves.

8. The method of claim 1, wherein the device comprises one of an integrated circuit and a microelectromechanical system device.

9. An apparatus, comprising:
a substrate having a substrate surface;
a device affixed to the substrate surface;
a bond pad on the substrate surface;
a lead coupling the device and the bond pad; and
a cap wafer affixed to the substrate surface, wherein the cap wafer comprises an outer wafer surface and an inner wafer surface having dicing grooves, wherein the inner wafer surface faces the substrate surface, and wherein the cap wafer is partially diced at portions of the outer wafer surface aligned with the dicing grooves on the inner wafer surface to expose the bond pad on the substrate surface.

10. The apparatus of claim 9, wherein the dicing grooves on the inner wafer surface are aligned between the bond pad and a bonding area, wherein the bonding area comprises an area at which the inner wafer surface is bonded to the substrate surface.

11. The apparatus of claim 9, wherein a width of the dicing grooves is such that cap wafer dust formed during partial dicing does not fall on the bond pad.

12. The apparatus of claim 9, wherein the cap wafer is partially diced at the portions of the outer wafer surface to a depth of the dicing grooves.

13. A method, comprising:
forming a plurality of dicing grooves in an inner surface of a cap wafer;
affixing a plurality of devices to a surface of a substrate;
forming a plurality of bond pads on the surface of the substrate, wherein the plurality of bond pads is coupled to the plurality of devices;
aligning the cap wafer and the substrate such that the inner surface of the cap wafer faces the surface of the substrate;
bonding the cap wafer to the substrate; and
partially dicing an outer surface of the cap wafer at portions of the outer surface corresponding to the plurality of dicing grooves in the inner surface of the cap wafer.

14. The method of claim 13, wherein aligning the cap wafer and the substrate comprises aligning the plurality of dicing grooves such that for each bond pad in the plurality of bond pads, a dicing groove in the plurality of dicing grooves is between the bond pad and a bonding area, wherein the bonding area comprises an area at which the cap wafer is bonded to the substrate.

15. The method of claim 14, wherein a width of the dicing groove is such that cap wafer dust formed during the partial dicing does not fall on the bond pad.

16. The method of claim 13, wherein bonding the cap wafer to the substrate comprises, for each device in the plurality of devices:
bonding a first portion of the inner surface of the cap wafer and a first portion of the surface of the substrate with a bonding polymer; and
bonding a second portion of the inner surface of the cap wafer and a second portion of the surface of the substrate with the bonding polymer, wherein the first and second portions of the surface of the substrate are on opposite sides of the device.

17. The method of claim 16, wherein:
the plurality of devices comprises a plurality of stress-sensitive devices;
the surface of the substrate further comprises a plurality of isolation trenches;
for each device in the plurality of devices, an isolation trench in the plurality of isolation trenches surrounds the device; and
forming the plurality of bond pads on the surface of the substrate comprises forming, for each device in the plurality of devices, a corresponding bond pad outside the corresponding isolation trench.

18. The method of claim 17, wherein the second portion of the surface of the substrate is between the corresponding isolation trench and the corresponding bond pad.

19. The method of claim 18, wherein aligning the cap wafer and the substrate comprises aligning, for each device in the plurality of devices, a dicing groove in the plurality of dicing grooves between the second portion of the surface of the substrate and the corresponding bond pad.

20. The method of claim 13, wherein partially dicing the outer surface of the cap wafer at portions of the outer surface corresponding to the plurality of dicing grooves comprises aligning at least one blade with the portions of the outer surface corresponding to the plurality of dicing grooves.

21. The method of claim 20, wherein partially dicing the outer surface of the cap wafer at portions of the outer surface corresponding to the plurality of dicing grooves further comprises sawing the at least one blade through the portions of the outer surface to a depth of the plurality of dicing grooves.

22. The method of claim 13, wherein the plurality of devices comprises at least one of an integrated circuit and a microelectromechanical system device.
